(19) United States
(12) Patent Application Publication
(10) Pub. No.: US 2026/0090306 A1
(43) Pub. Date: Mar. 26, 2026

(54) ELECTRONIC COMPONENT SEPARATED FROM WAFER BY BACK SIDE GROOVE AND GROOVE EXTENSION

(71) Applicant: Infineon Technologies AG, Neubiberg (DE)

(72) Inventors: Michael KRAUS, Sinzing (DE); Gunther MACKH, Neumarkt (DE)

(73) Assignee: Infineon Technologies AG, Neubiberg (DE)

(21) Appl. No.: 19/320,234

(22) Filed: Sep. 5, 2025

(30) Foreign Application Priority Data
Sep. 20, 2024 (DE) 10 2024 209 060.3

(51) Int. Cl. H01L 21/304; H01L 21/268; H01L 21/78

(52) U.S. Cl. CPC H10P 52/00; H10P 34/42; H10P 54/00

(57) ABSTRACT

A method of separating electronic components from a wafer is disclosed. In one example, the method comprises providing the wafer with a semiconductor substrate having a front side with an active region and having a back side covered by a functional layer. The wafer comprises a plurality of integrally connected electronic components arranged side-by-side, forming a back side groove extending through the functional layer into the semiconductor substrate between adjacent electronic components, and forming a groove extension connecting to the back side groove. The back side groove is formed with a maximum horizontal width larger than a maximum horizontal width of said groove extension.

### CROSS-REFERENCE TO RELATED APPLICATION

This Utility Patent Application claims priority to German Patent Application No. 10 2024 209 060.3 filed Sep. 20, 2024, which is incorporated herein by reference.

### BACKGROUND

### Technical Field

Various embodiments relate to a method of separating electronic components from a wafer, and an electronic component.

### Description of the Related Art

Packages may be denoted as for example encapsulated electronic chips with electrical connects and being mounted to an electronic periphery, for instance on a printed circuit board. Before packaging, a semiconductor wafer is separated into a plurality of electronic chips. After separating the wafer into the individual electronic chips, the electronic chips of the wafer may be subsequently used for further processing.

Separation may be accomplished by mechanically or laser dicing the wafer. However, a separation process may be slow and may lose a significant portion of a wafer usable for manufacturing electronic components, in particular in the case of smaller electronic components.

### SUMMARY

There may be a need to separate electronic components from a wafer with highly efficient use of wafer area and in a quick way.

According to an exemplary embodiment, a method of separating electronic components from a wafer is provided, wherein the method comprises providing the wafer with a semiconductor substrate having a front side with an active region and having a back side covered by a functional layer, said wafer comprising a plurality of integrally connected electronic components arranged side-by-side, forming a back side groove extending through the functional layer into the semiconductor substrate between adjacent electronic components, and forming a groove extension connecting to the back side groove to thereby form a through hole extending through the front side for separating adjacent electronic components from each other, wherein said back side groove is formed with a maximum horizontal width larger than a maximum horizontal width of said groove extension.

According to another exemplary embodiment, an electronic component is provided which comprises a semiconductor substrate, an active region at a front side of the semiconductor substrate, and a functional layer on a back side of the semiconductor substrate, wherein a sidewall of the electronic component has a notch extending laterally into the functional layer and into a connected portion of the semiconductor substrate.

According to an exemplary embodiment, an efficient and fast way of separating a wafer with an active region on the front side and with a functional layer on a back side into individual electronic components is provided. A corresponding separation method may form a back side groove through the functional layer and into part of the semiconductor substrate. Thereafter, the separation method may form a groove extension so that the back side groove and the groove extension are connected with each other for forming a through hole which contributes to the separation of the wafer into individual electronic components. Advantageously, said groove extension has a smaller maximum horizontal width than said back side groove. Beneficially, the separation method may remove only a small width of material from the front side adjacent to the active region which allows to obtain a large number of electronic components per wafer area with only small losses in a dicing street, for instance by plasma dicing. At the same time, the described manufacturing method allows a fast formation of the broader back side groove, for instance by mechanical dicing, which already separates the functional layer and additionally extends into part of the semiconductor substrate thickness, wherein the absence of the active region on the back side renders removal of a larger amount of material locally limited to the back side region uncritical in terms of efficient use of wafer volume. A correspondingly obtained electronic component may have, for example as a fingerprint of the described manufacturing process, a sidewall with a notch in the functional layer and in a connected portion of the semiconductor substrate. The mentioned notch may be located where the back side groove has been formed during the manufacturing process.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 shows a cross-sectional view of an electronic component according to an exemplary embodiment.

FIG. 2 shows a cross-sectional view of a wafer being already separated into a plurality of electronic components according to an exemplary embodiment.

FIG. 3 to FIG. 9 show cross-sectional views of structures obtained during carrying out a method of separating electronic components from a wafer according to an exemplary embodiment.

FIG. 10 shows a flowchart of a method of separating electronic components from a wafer according to an exemplary embodiment.

FIG. 11 to FIG. 17 show cross-sectional views of structures obtained during carrying out a method of separating electronic components from a wafer according to another exemplary embodiment.

### DETAILED DESCRIPTION

There may be a need to separate electronic components from a wafer with highly efficient use of wafer area and in a quick way.

According to an exemplary embodiment, a method of separating electronic components from a wafer is provided, wherein the method comprises providing the wafer with a semiconductor substrate having a front side with an active region and having a back side covered by a functional layer, said wafer comprising a plurality of integrally connected electronic components arranged side-by-side, forming a back side groove extending through the functional layer into the semiconductor substrate between adjacent electronic components, and forming a groove extension connecting to the back side groove to thereby form a through hole extending through the front side for separating adjacent electronic components from each other, wherein said back side groove is formed with a maximum horizontal width larger than a maximum horizontal width of said groove extension.

According to another exemplary embodiment, an electronic component is provided which comprises a semiconductor substrate, an active region at a front side of the semiconductor substrate, and a functional layer on a back side of the semiconductor substrate, wherein a sidewall of the electronic component has a notch extending laterally into the functional layer and into a connected portion of the semiconductor substrate.

According to an exemplary embodiment, an efficient and fast way of separating a wafer with an active region on the front side and with a functional layer on a back side into individual electronic components is provided. A corresponding separation method may form a back side groove through the functional layer and into part of the semiconductor substrate. Thereafter, the separation method may form a groove extension so that the back side groove and the groove extension are connected with each other for forming a through hole which contributes to the separation of the wafer into individual electronic components. Advantageously, said groove extension has a smaller maximum horizontal width than said back side groove. Beneficially, the separation method may remove only a small width of material from the front side adjacent to the active region which allows to obtain a large number of electronic components per wafer area with only small losses in a dicing street, for instance by plasma dicing. At the same time, the described manufacturing method allows a fast formation of the broader back side groove, for instance by mechanical dicing, which already separates the functional layer and additionally extends into part of the semiconductor substrate thickness, wherein the absence of the active region on the back side renders removal of a larger amount of material locally limited to the back side region uncritical in terms of efficient use of wafer volume. A correspondingly obtained electronic component may have, for example as a fingerprint of the described manufacturing process, a sidewall with a notch in the functional layer and in a connected portion of the semiconductor substrate. The mentioned notch may be located where the back side groove has been formed during the manufacturing process.

### Description of Further Exemplary Embodiments

In the following, further exemplary embodiments of the method and the electronic component will be explained.

In the context of the present application, the term “wafer” may particularly denote a semiconductor-based plate or disk which has been processed to form a plurality of integrated circuit elements in an active region of the wafer and which may be singulated into a plurality of separate electronic components or chips. For example, a wafer may have a matrix-like arrangement of electronic components in rows and columns. It is possible that a wafer has a circular geometry or a polygonal geometry (such as a rectangular geometry or a triangular geometry).

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a pressure sensor, a light sensor or a gas sensor), an actuator (for instance a loudspeaker), and a microelectromechanical system (MEMS, for instance a loudspeaker, a member comprising a mechanical spring, etc.). However, in other embodiments, the electronic component may also be of different type, such as a mechatronic member, in particular a mechanical switch, etc.

In the context of the present application, the term “semiconductor substrate” may particularly denote a body comprising a semiconductor material. The semiconductor body may be initially part of a semiconductor wafer and may be separated from the wafer compound during a manufacturing process. For example, the semiconductor body comprises silicon or silicon carbide. The semiconductor body may be predominantly made of a semiconductor material. For instance, the semiconductor body may be a plate-shaped structure or a cuboid-shaped structure or a disk-shaped structure.

In the context of the present application, the term “active region” may particularly denote a surface region of a semiconductor substrate of a wafer or an electronic component, in and/or on which surface region at least one monolithically integrated circuit element (such as a transistor, a diode, a capacitance, a resistor, etc.) is formed. In particular, such an active region may form a surface region of a wafer or an electronic component at a front side thereof.

In the context of the present application, the term “functional layer” may particularly denote a layer which may be arranged at (for instance attached to) the back side of a wafer or electronic component for providing an assigned function during use of the readily manufactured electronic component and/or during manufacture of the electronic component. For example, the functional layer may be a dark tape. However, many different functions may be fulfilled by a functional layer, such as an electrical and/or a thermal insulation function, an electrical and/or a thermal conduction function, a mechanical function, a protection function against chemical and/or physical impact, and/or an optical function, such as shielding or absorbing light or enhancing contrast.

In the context of the present application, the term “back side groove” may particularly denote a long narrow channel or depression extending into the back side of the semiconductor substrate. A back side groove may extend along a plurality of juxtaposed electronic components of a wafer. Hence, a back side groove may be an elongate blind hole extending through the functional layer and part of the semiconductor substrate. The back side groove may be straight and/or curved. A plurality of back side grooves may be formed along rows and columns for contributing to the separation of a two-dimensional wafer into individual electronic components. Each separated electronic component may be surrounded by four back side grooves along four sidewalls of the electronic component.

In the context of the present application, the term “groove extension” may particularly denote a void region extending from the front side of the semiconductor substrate up to the back side groove. Consequently, groove extension and back side groove may together form a through hole extending through the entire wafer. In particular, the groove extension-without the connected back side groove-may be a front side groove, i.e. a long narrow channel or depression extending into the front side of the semiconductor substrate. The groove extension may have a single continuous width along its entire vertical extension, or may have two or more vertical sections of different widths. The groove extension may be straight and/or curved. A plurality of groove extensions may be formed along rows and columns for contributing to the separation of a two-dimensional wafer into individual electronic components. Each separated electronic component may be surrounded by four groove extensions along four sidewalls of the electronic component.

In the context of the present application, the term “through hole” may particularly denote a void region extending the entire way between the front side and the back side of the semiconductor substrate including the functional layer thereon. Said through hole may be elongate. Said through holes may have a straight and/or curved shape. A plurality of through holes may be formed along rows and columns for separating a two-dimensional wafer into individual electronic components.

In the context of the present application, the term “maximum horizontal width” may particularly denote the largest horizontal width along an entire vertical extension of a groove, recess, hole or void structure, such as a back side groove or a groove extension or part thereof, extending through at least part of the semiconductor substrate and/or the functional layer.

In the context of the present application, the term “notch” may particularly denote a sidewall recess. The notch may be defined in a portion of the semiconductor substrate and in the functional layer thereon. A further notch may be optionally defined in another portion of the semiconductor substrate and in a back end of the line structure thereon. For instance, such a notch may be a blind hole in a sidewall. Such a notch may be delimited exclusively by material of the semiconductor substrate and of the functional layer or by material of the semiconductor substrate and of the back end of the line structure. Such a notch may be circumferentially closed around an electronic component, for instance in an annular fashion.

In an embodiment, the method comprises forming the back side groove by mechanically dicing or by laser dicing. In particular mechanically dicing may lead to a fast singulation process, while a resulting relatively broad scribe line on the back side does not negatively influence the number of electronic components obtainable per wafer.

In an embodiment, the method comprises forming the groove extension by processing from the front side until the groove extension connects with the back side groove. Processing the back side groove from the back side and the groove extension from the front side may lead to a simple separation process.

However, in another embodiment, the groove extension may also be formed by processing from the back side.

In an embodiment, the method comprises forming at least part of the groove extension by plasma dicing. Advantageously, plasma dicing may lead to a very narrow scribe line which may have a positive impact on the number of electronic components obtainable per wafer.

In an embodiment, the method comprises forming the groove extension by two processing stages, in particular by two dicing stages. For example, the first one may be specifically adjusted for opening a back end of the line structure, whereas the second one may be specifically adjusted for obtaining a narrow scribe line for obtaining a large number of electronic components per wafer.

In an embodiment, the method comprises forming an exterior portion of the groove extension extending up to the front side by laser grooving. Advantageously, laser grooving may be capable of cutting through a back end of the line structure.

In an embodiment, the method comprises forming an interior portion of the groove extension vertically between the back side groove and the exterior portion by plasma dicing. Plasma dicing made be an excellent choice for obtaining a narrow scribe line in an interior of the semiconductor body so that a large number of electronic components per wafer may be obtained.

In an embodiment, the method comprises providing the semiconductor substrate with a back end of the line (BEOL) structure on the active region and forming the groove extension to extend through the back end of the line structure. Such a back end of the line structure may comprise a metallization pattern which can be diced for instance by laser grooving.

In an embodiment, the method comprises forming the back side groove with a maximum horizontal width in a range from 20 μm to 50 μm, in particular in a range from 25 μm to 35 μm. Although being relatively large, such as scribe line on the back side does not have a negative impact on the number of electronic components per wafer in view of the absence of the active region on the back side. However, it may advantageously lead to a fast first part of the singulation process.

In an embodiment, the method comprises forming an exterior portion of the groove extension with a maximum horizontal width in a range from 10 μm to 35 μm, in particular in a range from 15 μm to 25 μm. A corresponding scribe line may be formed by laser grooving. The moderate width of the scribe line of such a process may be compatible with an efficient use of wafer area while enabling opening a BEOL structure.

In an embodiment, the method comprises forming an interior portion of the groove extension with a maximum horizontal width in a range from 5 μm to 30 μm, in particular in a range from 10 μm to 20 μm. Such an extremely small scribe line, being obtainable by plasma dicing, may advantageously lead to a very high number of electronic components per wafer.

In an embodiment, the method comprises forming the back side groove wider (in particular with a larger maximum horizontal width) than an exterior portion of the groove extension, wherein in particular an interior portion of the groove extension is formed narrower (in particular with a smaller maximum horizontal width) than the exterior portion of the groove extension. This configuration may be obtained by forming the back side groove by mechanical dicing, the exterior portion of the groove extension by laser grooving and the interior portion of the groove extension by plasma dicing.

In an embodiment, the method comprises forming the interior portion of the groove extension with substantially vertical sidewalls. Such a geometry may be obtained by plasma dicing.

In an embodiment, the method comprises forming a concave tapering section at an interface between the exterior portion of the groove extension and the interior portion of the groove extension. Such a concave tapering section may be a fingerprint of laser grooving for forming said exterior portion.

In an embodiment, the method comprises forming a concave tapering section at an interface between the back side groove and the interior portion of the groove extension. Such a concave tapering section may be a fingerprint of mechanical dicing for forming said back side groove.

In an embodiment, the method comprises forming electrically conductive connection structures on the front side and embedding the electrically conductive connection structures in a temporary protection carrier, thereafter thinning the semiconductor substrate at the back side, thereafter forming said functional layer on the back side of the thinned semiconductor substrate before forming said back side groove, and removing said temporary protection carrier forming said back side groove. For instance, the electrically conductive connection structures may be solder structures, in particular solder bumps or solder balls. Other electrically conductive connection structures are possible, such a sinter structures or electrically conductive glue. An electrically conductive connection structure may be protected against impact (in particular may be protected against slurry or debris) during thinning the semiconductor substrate by grinding by covering the electrically conductive connection structure temporarily with a protection carrier. The latter may be removed after thinning the semiconductor substrate and after forming as well as dicing the functional layer.

In an embodiment, the method comprises forming electrically conductive connection structures on the front side and coating the electrically conductive connection structures by a plasma resistant coating, thereafter, forming said groove extension in the semiconductor substrate and extending through the plasma resistant coating, and thereafter removing said plasma resistant coating. Advantageously, the electrically conductive connection structures (such as solder bumps) may be protected temporarily against the impact of plasma dicing. Further advantageously, a corresponding temporary plasma resistant coating may also be compatible with a laser process which may be used when forming a groove extension.

In an embodiment, a transition between the functional layer and the connected portion of the semiconductor substrate at the notch is continuous and stepless. In particular, functional layer and semiconductor substrate may delimit a vertical, slanted and/or curved notch surface without discontinuity in between. This may be the result of a formation of the notch by mechanical dicing.

In an embodiment, the sidewall has a step between the notch and a further connected portion of the semiconductor substrate. Such a geometrical feature at the sidewall of the electronic component may be obtained when forming the notch by mechanical dicing.

In an embodiment, the further connected portion has a vertical section adjacent to the step, wherein in particular the further connected portion has a further notch adjacent to the vertical section, wherein more particularly the notch extends laterally deeper into the semiconductor substrate than the further notch. The vertical section may be obtained by forming a corresponding sidewall portion by plasma dicing. The further notch may be the result of a formation of a corresponding sidewall portion by laser grooving. A notch formed by laser grooving may be less pronounced than a notch formed by mechanical dicing.

In an alternative embodiment, the vertical section of the further connected portion extends from the step straight up to the front side. Thus, it may be possible that a further step is missing (for example if material does not contain low dielectrics in the back end of the line stack). Then the grooving forming the further notch may be replaced with plasma etching, so that the further step may then be omitted and the trench already has the width of the vertical section.

In an embodiment, the functional layer comprises at least one of a protection layer, an isolation layer, a metallization layer, a plastic layer, a die attach layer, an opaque layer, and an optical contrast enhancing layer. The functional layer may be a permanent functional layer forming part of the readily manufactured electronic component. For instance, a function of the functional layer may be protection, isolation, contribution to die attachment, the provision of a dark color so that an optical inspection of the electronic components is not disturbed by light refraction, a marking function, or the provision of a metal reservoir for improving attachment or for shielding. The functional layer may be electrically insulating, electrically conductive, light absorbing, contrast-enhancing, and/or protective against mechanical and/or chemical impact.

In an embodiment, the electronic component is a power semiconductor chip. Such a power semiconductor chip may have integrated therein one or multiple integrated circuit elements such as transistors (for instance field effect transistors like metal oxide semiconductor field effect transistors and/or bipolar transistors such as insulated gate bipolar transistors) and/or diodes. Exemplary applications which can be provided by such integrated circuit elements are switching purposes. For example, such an integrated circuit element of a power semiconductor device may be integrated in a half-bridge or a full bridge. Exemplary applications are automotive applications.

The electronic component (in particular semiconductor chip) may comprise at least one of the group consisting of a diode, and a transistor, more particularly an insulated gate bipolar transistor. For instance, the electronic chip may be used as semiconductor chip for power applications for instance in the automotive field. In an embodiment, at least one semiconductor chip may comprise a logic IC or a semiconductor chip for RF power applications. In one embodiment, the semiconductor component may be used as one or more sensors or actuators in microelectromechanical systems (MEMS), for example as pressure sensors or acceleration sensors, as a microphone, as a loudspeaker, etc.

As substrate or wafer for the semiconductor components, a semiconductor substrate, i.e. a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

Furthermore, exemplary embodiments may make use of standard semiconductor processing technologies such as appropriate etching technologies (including isotropic and anisotropic etching technologies, particularly plasma etching, dry etching, wet etching), patterning technologies (which may involve lithographic masks), deposition technologies (such as chemical vapor deposition (CVD), plasma enhanced chemical vapor deposition (PECVD), atomic layer deposition (ALD), sputtering, etc.).

The illustration in the drawing is schematically and not to scale.

Before exemplary embodiments will be described in more detail referring to the figures, some general considerations will be summarized based on which exemplary embodiments have been developed.

Plasma dicing may be a preferred separation method for very small dies due to smaller required scribe line width (for example about 30 μm) compared to other methods. Thus, separation of electronic components from a wafer by plasma dicing may lead to a significant increase of the number of obtainable semiconductor dies per wafer.

For example, a typical die size for certain applications may be 600×600 μm² or 600×1200 μm². Considering a typical scribe line width of for example 60 μm shows that a large amount of wafer area is lost by singulation. More specifically, plasma dicing may reduce a scribe line width from 60 μm to 24 μm, which may result in a significant increase of the number of dies per wafer. A loss of wafer area by dicing may be in particular problematic when expensive wafers are processed, in particular due to a complex wafer-to-wafer bonding process. In view of the foregoing, an increase of the number of semiconductor dies per wafer is highly desirable. Enabling of plasma dicing could safe a significant amount of scribe line width, for example 30 μm of scribe line width, compared with a mechanical dicing process.

However, there may be applications and scenarios in which plasma dicing is not desired or not considered possible. For example, there may be applications which require a back side protection tape which cannot be separated by plasma. Also applications using a die thickness of 200 μm to 250 μm may be too thick for efficient plasma dicing. When a solder ball, for instance with 170 μm diameter, shall be provided on an electronic component, a thick coating during plasma is needed, which may render the manufacturing process more complex.

According to an exemplary embodiment, a semiconductor wafer may be highly efficiently separated into individual electronic components. The wafer and each of the electronic components being initially still integrally connected in the wafer compound may have an active region with integrated circuitry on the front side and an attached functional layer on a back side. A separation process may firstly comprise forming a back side groove extending through functional layer and a connected part of the semiconductor substrate of the wafer. In one or more additional processing stages, a groove extension may be formed in the front side with its active region and aligned with the back side groove so that front side groove and groove extension together separate the wafer into individual electronic components. Beneficially, the groove extension may be laterally narrower than the back side groove so that only a small amount of material is removed during separation from the front side with its active region. Consequently, a number of electronic components obtainable from a wafer may be rendered very high thanks to the only minor losses due to dicing in the front side. A larger material loss on the back side may be acceptable, since the back side is spatially apart from the active region so that a dicing technology ensuring a rapid back side groove formation may be used for accelerating the singulation process. An electronic component obtained, for instance, from such a manufacturing method may have a notched sidewall portion on the back side which is covered by the functional layer. Said notch may be the fingerprint of the formation of the back side groove during singulation.

More specifically, exemplary embodiments may enable plasma dicing for singulating electronic components with permanent back side adhesive tape, as an example for a functional layer. Said functional layer together with a connected semiconductor portion may be subjected to mechanical dicing for forming a back side groove in a fast way. Thereafter, a groove extension may be formed in the front side at least partially by plasma dicing, optionally and preferably supported by laser grooving. Thanks to plasma dicing, a very small scribe line may be achieved on the front side leading to a large number of electronic components per wafer. Hence, the semiconductor thickness may be locally reduced with a fast mechanical dicing method, such as mechanical dicing, for opening the back-sided functional layer into the semiconductor substrate. Thereafter, an optional laser dicing process (which may have a narrower scribe line as the above-mentioned mechanical dicing process) may be executed from the front side which may dice through a back end of the line structure and a further part of the semiconductor substrate, and the rest of the wafer thickness may then be cut through by plasma etching with a very narrow scribe line.

In an embodiment, a method to plasma dice a die with a backside adhesive tape is provided. More specifically, a method of wafer plasma dicing may be provided, wherein the wafer comprises an adhesive tape on its back side. The method may comprise grinding the wafer and laminating its back side with tape, mechanically dicing and creating half-cuts in the back side, applying a plurality of balls on the front side and embedding them in the tape, applying dicing tape on the back side, coating balls and front side with a coating material of high viscosity (such as a laser and plasma compatible coating), laser grooving the front side, plasma dicing of the die, and rinsing (for instance with water).

By integrating plasma dicing from the front side in the singulation process, a small scribe line (for instance in a range from 10 μm to 20 μm) may be obtained, which may be significantly smaller than a scribe line width obtained by mechanical dicing. This may increase the number of dies per wafer. Beneficially, mechanical dicing from the back side may allow to cut through the tape or other kind of functional layer (for instance with a scribe line width in a range from 25 μm to 40 μm). Thus, such a process may allow an easy patterning of the back side tape. Furthermore, an efficient mechanical dicing process may be possible by a single cut and a high feed speed. Furthermore, a mechanical dicing process may operate on an unseparated wafer. Since a die-to-die distance on the front side may be smaller than a dicing channel, the dicing blade width does not limit number of dies per wafer. Further advantageously, the execution of a mechanical dicing process for groove formation may allow to extend the die thickness range to thicknesses which are not efficient for pure plasma dicing. Moreover, die knocking during pick-up may be less probable due to higher die-to-die distance on the back side.

In a further embodiment, it may be possible to reduce a plasma etching width to 3 μm to 10 μm and to use tape expansion to achieve a final die-to-die distance.

In yet another embodiment, it may be possible to change the order of processing, i.e. to execute front side processing before back side processing.

Moreover, a process flow may be with or without balls or pillars, which are thus optional.

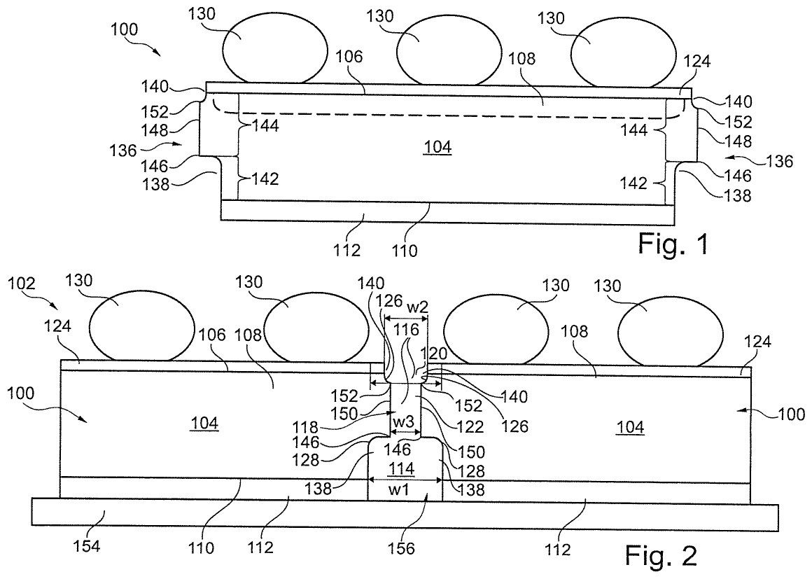

FIG. 1 shows a cross-sectional view of an electronic component 100 according to an exemplary embodiment. The illustrated electronic component 100 may be a semiconductor die, for instance a power semiconductor die.

In its vertically central portion, the electronic component 100 comprises a semiconductor substrate 104, for instance a silicon body. For example, a thickness of the semiconductor substrate 104 may be in a range from 100 μm to 500 μm, for instance 250 μm. An active region 108 may be formed in a front side portion at a front side 106 of the semiconductor substrate 104. For instance, the active region 108 may extend up to depth of 10 μm to 40 μm, in particular 20 μm to 30 μm, into the semiconductor substrate 104. For example, the active region 108 may comprise one or more monolithically integrated circuit elements, such as a field-effect transistor and/or a diode. The active region 108 may be formed by semiconductor technology processing.

A back end of the line (BEOL) structure 124 may be formed on the active region 108. The back end of the line structure 124 may comprise for example metal interconnect layers on the semiconductor substrate 104 being already patterned and connected with integrated device(s) in the active region 108. The back end of the line structure 124 may also interconnect one or more integrated circuit elements (such as transistors, capacitors, resistors, etc.) with a metal wiring. For example, the back end of the line structure 124 may comprise a front side metallization with a patterned stack of metallic layers.

As shown as well, electronic component 100 may comprise one or more electrically conductive connection structures 130 on the back end of the line structure 124 above the active region 108. For example, such an electrically conductive connection structure 130 may be a solder bump. In the shown embodiment, a plurality of solder bumps embodied as solder balls, for instance having a diameter of 170 μm, are provided. Alternatively, other electrically conductive connection structures 130 may be foreseen, for instance a sinter paste, an electrically conductive glue, etc.

Opposing to the front side 106 of the semiconductor substrate 104 is a back side 110 thereof. A functional layer 112 may be attached to the back side 110 of the semiconductor substrate 104. For example, a vertical thickness of the functional layer 112 may be in a range from 10 μm to 50 μm. In the shown embodiment, the functional layer 112 may be a black tape, for instance comprising a plastic material, attached to the back side 110. The functional layer 112 remains permanently attached to the semiconductor substrate 104 and may thus be denoted as a permanent functional layer 112. However, the functional layer 112 may have different functions in other embodiments. For instance, the functional layer 112 may be a protection layer (for example protecting the interior of the electronic component 100 against a chemical or mechanical impact), an isolation layer (for example protecting the electronic component 100 against electric creepage current), a metallization layer (for example for shielding the electronic component 100 against electromagnetic radiation), a die attach layer (for instance comprising an adhesive for attaching the electronic component 100 to a support), an opaque layer (for protecting the electronic component 100 against light), and/or an optical contrast enhancing layer (for instance for enhancing optical contrast or for engraving alphanumerical information).

Sidewalls 136 of the electronic component 100 form a circumferential and lateral boundary surface of the electronic component 100 between the horizontal front side 106 and the horizontal back side 110. For example, the electronic component 100 may have a substantially rectangular or cuboid shape. For example, each of four circumferential sidewall portions may have a shape of the opposing sidewalls 136 shown in FIG. 1. As shown, each of the shown two opposing sidewalls 136 has a notch 138 extending laterally into the functional layer 112 and into a connected portion 142 of the semiconductor substrate 104. More specifically, the notch 138 extends laterally into the entire functional layer 112 and into a connected portion of the semiconductor substrate 104 starting from the back side 110 and extending up to a central portion of the semiconductor substrate 104. As shown, a transition between the functional layer 112 and the connected portion 142 of the semiconductor substrate 104 at the notch 138 is continuous and stepless. Hence, no structural discontinuity is present in the notch 138 at the back side 110 forming an interface between the functional layer 112 and the semiconductor substrate 104. Although not shown, the sidewall 136 may have the notch 138 extending along an entire circumference of the electronic component 100. Thus, the notch 138 may be a closed loop notch extending along the lateral perimeter of the electronic component 100.

Referring to FIG. 1, each of the sidewalls 136 may have a step 146 between the notch 138 and a further connected portion 144 of the semiconductor substrate 104. Said further connected portion 144 may extend from the step 146 at the upper end of the notch 138 towards the front end 106 of the semiconductor substrate 104. As shown, the further connected portion 144 has a straight vertical section 148 adjacent to the step 146 and extending from the step 146 upwardly up to a further step 152. For instance, a vertical thickness of the sidewall section between the step 146 and the further step 152 may be in a range from 20 μm to 150 μm. Moreover, the further connected portion 144 has a further notch 140 adjacent to the vertical section 148 and extending from the further step 152 upwardly up to the front side 106 and beyond through the entire back end of the line structure 124. For example, a vertical extension of the further notch 140 may be in a range from 5 μm to 20 μm. As can be taken from FIG. 1 as well, the deeper notch 138 extends laterally deeper into the semiconductor substrate 104 than the shallower further notch 140.

In an alternative embodiment (not shown), the vertical section 148 of the further connected portion 144 may extend from the step 146 straight up to the front side 106 and optionally also through the back end of the line structure 124. Thus, it may be possible that further notch 140 and further step 152 are missing (for example if the material does not contain low dielectrics in the back end of the line structure 124). Then the grooving or further notch 140 formed by laser processing (as described below) may be omitted, for instance when replacing said laser processing with plasma etching. The further step 152 may then be omitted and the entire portion of the sidewall 136 above step 146 already has the width of the vertical section 148 up to the upper main surface of the electronic component 100.

For example, the electronic component 100 of FIG. 1 may be formed by the manufacturing process described below referring to FIG. 3 to FIG. 9. The above-described alternative without further notch 140 may be obtained by said manufacturing process with the precaution that the two-stage laser processing and plasma dicing into the front side 106 may be substituted by a single plasma dicing process without laser processing. The plasma dicing process may be slower than a mechanical dicing process used for forming notch 138, but may lead to a narrow bottleneck in an interior of the wafer 102 between two adjacent electronic components 100. Advantageously, the use of plasma dicing may save wafer area and may increase the yield of electronic components 100 due to a narrow plasma dicing scribe line.

FIG. 2 shows a cross-sectional view of a wafer 102 being already separated into a plurality of electronic components 100 according to an exemplary embodiment. The below description of FIG. 3 to FIG. 9 will demonstrate how the structure of FIG. 2 can be obtained. Referring to FIG. 2, some geometrical attributes of said structure will be described. FIG. 2 shows two electronic components 102 arranged side-by-side adjacent to each other and which have been separated from a common wafer 102. The separated electronic components 100 of FIG. 2 are still mounted on a common dicing tape 154. Between the adjacent electronic components 100, a through hole-type separation channel or trench 156 is formed which extends through the functional layer 112, the entire semiconductor substrate 104 from the front side 106 to the back side 110 and the back end of the line structure 124.

As shown in FIG. 2, a back side groove 114—forming notch 138 of the electronic components 100—in the wafer 102 is formed with a maximum horizontal width w1 preferably in a range from 25 μm to 35 μm. For instance, a vertical extension of the back side groove 114 may be at least 50%, in particular at least 60%, of the thickness of the electronic component 100. The backside groove 114 may be formed preferably by mechanical dicing using a dicing blade, or by laser ablation. Furthermore, an exterior portion 120 of a groove extension 116—forming further notch 140 of the electronic components 100—in the wafer 102 is formed with a maximum horizontal width w2 which is preferably in a range from 15 μm to 25 μm. Moreover, an interior portion 122 of the groove extension 116—forming straight vertical section 148 of the electronic components 100—in the wafer 102 is formed with a maximum horizontal width w3 preferably in a range from 10 μm to 20 μm. The maximum horizontal width w3 may also be denoted as plasma etching width, since it may be defined by a plasma etching process. As shown, the mentioned maximum horizontal widths w1, w2, w3 are formed to fulfil the condition w1>w2>w3. Advantageously, w2 and w3 are smaller than w1 which allows an efficient use of the area of the wafer 102 for forming a large number of electronic components 100 without excessive losses by scribe lines. The section according to w1 can however be formed with a fast mechanical dicing process without having an impact on the active region 108 of the respective electronic component 100. Hence, an efficient use of a wafer area may be synergistically combined with a rapid dicing process.

A minimum opening required for plasma etch (of for example 10 μm to 20 μm) may correspond to a bottom laser grooving width. A laser grooving top width (corresponding to maximum horizontal width w2) may be for example in a range from 15 μm to 25 μm. Furthermore, a taper may be formed between top grooving width and bottom grooving width (due to a laser profile), for instance having a dimension of about 5 μm.

FIG. 3 to FIG. 9 show cross-sectional views of structures obtained during carrying out a method of separating electronic components 100 from a wafer 102 according to an exemplary embodiment.

Referring to FIG. 3, the wafer 102 is provided in a condition in which the formation of integrated circuit elements in the wafer 102 is completed. The wafer 102 is provided with a semiconductor substrate 104, such as a silicon body, having a front side 106 with an active region 108 and integrated circuit elements and having a back side 110. The wafer 102 comprises a plurality of still integrally connected electronic components 100, such as semiconductor dies, arranged side-by-side. For instance, the still integrally connected electronic components 100 may be arranged in rows and columns within the wafer compound. As shown, the semiconductor substrate 104 is provided with a back end of the line structure 124, i.e. a BEOL stack such as a patterned metallization, on the active region 108. Furthermore, electrically conductive connection structures 130, such as solder bumps, may be formed on the front side 106. For instance, the electrically conductive connection structures 130 may have a diameter in a range from 100 μm to 250 μm, for instance may be solder balls with a diameter of 170 μm. After having singulated individual electronic components 100, an electronic component 100 may be connected with an electronic periphery, for instance a mounting base such as a printed circuit board or a carrier such as a leadframe structure, by establishing a solder connection using the solder-type electrically conductive connection structures 130.

The wafer 102 shown in FIG. 3 is ready for separation into the individual electronic components 100 thereof. Hence, FIG. 3 shows the incoming wafer 102 after ball apply and wafer testing.

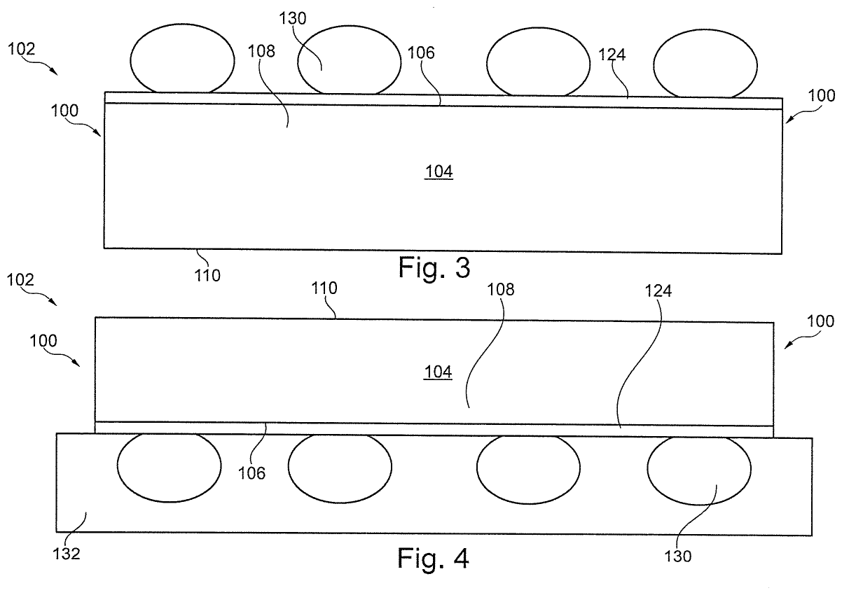

Referring to FIG. 4, the electrically conductive connection structures 130 may be embedded in a temporary protection carrier 132. For example, the temporary protection carrier 132 may be a grinding tape or a glass carrier. The temporary protection carrier 132 may be used for embedding the ball-shaped electrically conductive connection structures 130 for protecting them during a subsequent thinning process, in particular with respect to slurry or grinding debris generated during such a thinning process.

Thereafter, the obtained structure may be subjected to thinning on the back side 110 by removing material of the semiconductor substrate 104 from the back side 110 until a target thickness of the semiconductor substrate 104 is achieved. For instance, this may be accomplished by mechanically grinding.

Referring to FIG. 5, a functional layer 112, such as a back side protection tape, is attached to the back side 110 after thinning. For instance, this may be done by an adhesive or by lamination. Thus, said functional layer 112 may be formed on the back side 110 of the thinned semiconductor substrate 104 before forming a back side groove 114. Thereafter, the process continues with the formation of the back side groove 114 extending through the functional layer 112 into the semiconductor substrate 104 between adjacent electronic components 100. Advantageously, the back side groove 114 is formed by a fast dicing process such as mechanically dicing. Alternatively, laser dicing may be carried out for forming the back side groove 114 extending through the entire functional layer 112 and a back side portion of the semiconductor substrate 104. The process of forming the back side groove 114 ends in an interior of the semiconductor substrate 104. During the described mechanical dicing from the back side 110 of the semiconductor substrate 104, a back side alignment may be advantageous. For instance, such a back side alignment may be accomplished by capturing a camera image from a bottom side.

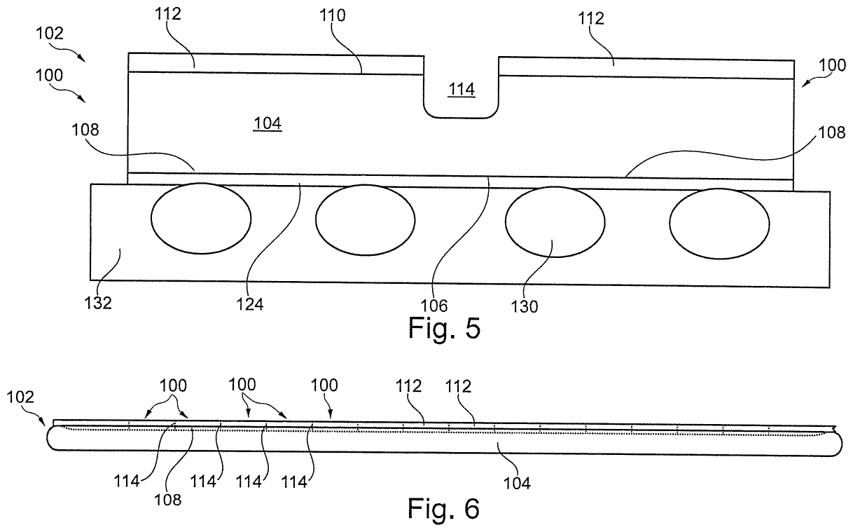

Referring to FIG. 6, a cross-sectional view of the entire wafer 102 is shown after having formed a plurality of parallel back side grooves 114 each between two adjacent electronic components 100. Also in a direction in the surface plane of the wafer 102 perpendicular to said back side grooves 114, further back side grooves 114 may be formed for separating all four sides of a respective electronic component 100. Optionally, no cutting is executed across a wafer edge (such as a dive in) for stabilization.

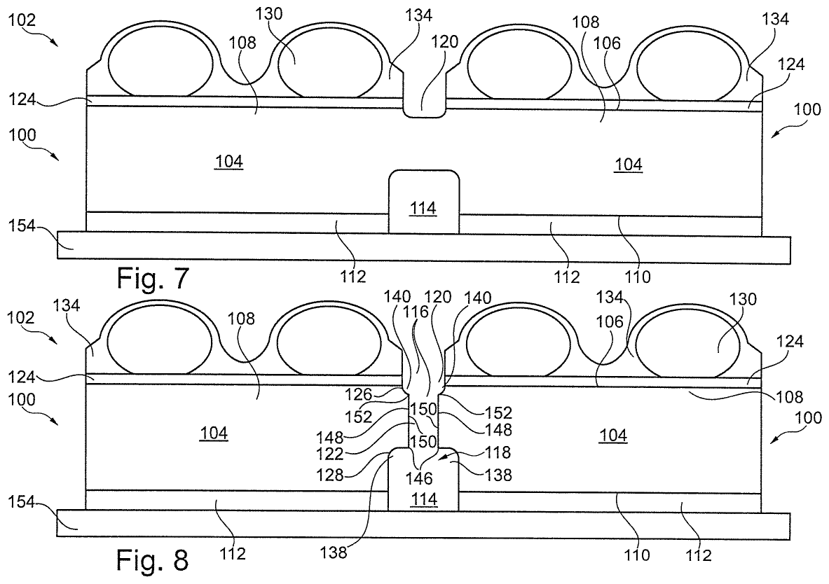

Referring to FIG. 7, the functional layer 112, which has meanwhile been structured by the back side groove 114, has been mounted on a dicing type 154. Furthermore, the temporary protection carrier 132 may be removed after thinning and after having formed said back side groove 114. Thereafter, the exposed electrically conductive connection structures 130 may be coated by a plasma resistant coating 134. This plasma resistant coating 134 protects the electrically conductive connection structures 130 during a later plasma dicing process. Furthermore, this plasma resistant coating 134 may also provide a certain protection for the electrically conductive connection structures 130 during a subsequent laser process. Thus, the material of the plasma resistant coating 134 may be a laser and plasma compatible coating material, preferably having a high viscosity.

Thereafter, a first process of two processes for forming a groove extension 116 is executed. By this first process, an exterior portion 120 of the groove extension 116 is formed which extends into the front side 106 by laser grooving. As shown in FIG. 7, the exterior portion 120 of the groove extension 116 extends through the entire thickness of the plasma resistant coating 134, through the back end of the line structure 124 and into a front-sided portion of the semiconductor substrate 104. As shown, the laser grooving process is executed from the front side 106. As can be taken from FIG. 7 as well, a horizontal width of the exterior portion 120 of the groove extension 116 being presently formed is smaller than a horizontal width of the back side groove 114. This is due to the fact that the exterior portion 120 is formed by laser grooving, whereas the back side groove 114 is formed by mechanical dicing.

Summarizing, the wafer 102 may be mounted with its functional layer 112 on dicing tape 154, the plasma resistant coating 134 is provided with laser and plasma compatible coating material with high viscosity on the electrically conductive connection structures 130, and then laser grooving is executed from the front side 106.

Referring to FIG. 8, the second process of the two-stage process for forming the groove extension 116 is executed for completing separation of the individual electronic components 100. During said second process, the remaining thickness of the semiconductor substrate 104 between the exterior portion 120 of the groove extension 116 and the back side groove 114 is bridged by removing further material of the semiconductor substrate 104 in between by plasma dicing from the front side 106 to thereby form a narrow interior portion 122 of the groove extension 116. Thus, formation of the groove extension 116 may be completed, said groove extension 116 connecting to the back side groove 114 to thereby form a through hole 118 extending vertically through the entire wafer 102 for separating adjacent electronic components 100 from each other. Advantageously, the groove extension 116 may be formed with its exterior portion 120 by laser grooving and with its interior portion 122 by plasma dicing. Thus, forming the interior portion 122 of the groove extension 116 vertically between the back side groove 114 and the exterior portion 120 may be accomplished by plasma dicing. Plasma dicing may be executed until the opposing back side groove 114 or sawing hole is reached. Thus, the groove extension 116 may be formed by processing from the front side 106 until the groove extension 116 connects with the back side groove 114. In particular, plasma dicing may be accomplished by using reactive ion etching (RIE). Advantageously, plasma dicing may be capable of forming very narrow scribe lines so that only a minimum amount of wafer volume is lost by the singulation process and a high number of electronic components 100 per area of wafer 102 may be obtained. After having formed the groove extension 116, the individual electronic components 100 are separated from the wafer compound. As shown, a plurality of electronic components 100 according to FIG. 1 may be obtained.

It may be possible that the interior portion 122 of the groove extension 116 is formed with substantially vertical sidewalls 150 in the straight vertical section 148. Furthermore, a concave tapering section 126 may be formed at an interface between the exterior portion 120 of the groove extension 116 and the interior portion 122 of the groove extension 116. Moreover, another concave tapering section 128 may be formed at an interface between the back side groove 114 and the interior portion 122 of the groove extension 116.

Referring also to FIG. 2, said back side groove 114 is formed with a maximum horizontal width w1 larger than a maximum horizontal width w2 of said groove extension 116. The smallest width at a bottleneck of the through hole 118 between two separated electronic components 100 may be the maximum horizontal width w3 in the interior portion 122 formed by plasma dicing. Accordingly, the back side groove 114 may be wider than the exterior portion 120 of the groove extension 116, wherein the interior portion 122 of the groove extension 116 is formed even narrower than the exterior portion 120 of the groove extension 116.

In another embodiment (not shown), it may be also possible to form the entire groove extension 116 by a single further dicing process, preferably by plasma dicing only.

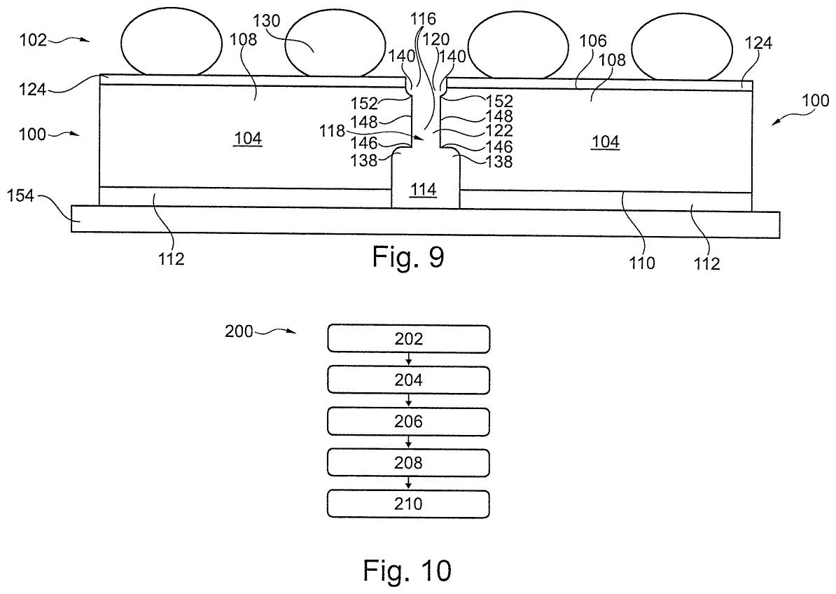

Referring to FIG. 9, said plasma resistant coating 134 may be removed for exposing the electrically conductive connection structures 130. This removal process may be embodied for instance as a water rinse process. Thereafter, the electronic components 100 may be removed from the dicing tape 154. The readily manufactured electronic components 100 may be used, for instance for packaging. This may involve establishing a solder connection between the exposed electrically conductive connection structures 130 and another electronic member.

FIG. 10 shows a flowchart 200 of a method of separating electronic components 100 from a wafer 102 according to an exemplary embodiment.

Referring to block 202 (compare FIG. 3), electrically conductive connection structures 130 are formed on a front side 106 of the wafer 102.

Referring to block 204 (compare FIG. 4), the obtained structure is subjected to thinning on back side 110.

Referring to block 206 (compare FIG. 5), a functional layer 112 is attached to the back side 110, and a back side groove 114 is formed.

Referring to block 208 (compare FIG. 7), a first process of two processes for forming a groove extension 116 is executed by forming an exterior portion 120 of the groove extension 116 which extends into the front side 106.

Referring to block 210 (compare FIG. 8), a second process of the two-stage process for forming the groove extension 116 is executed for completing separation of the individual electronic components 100.

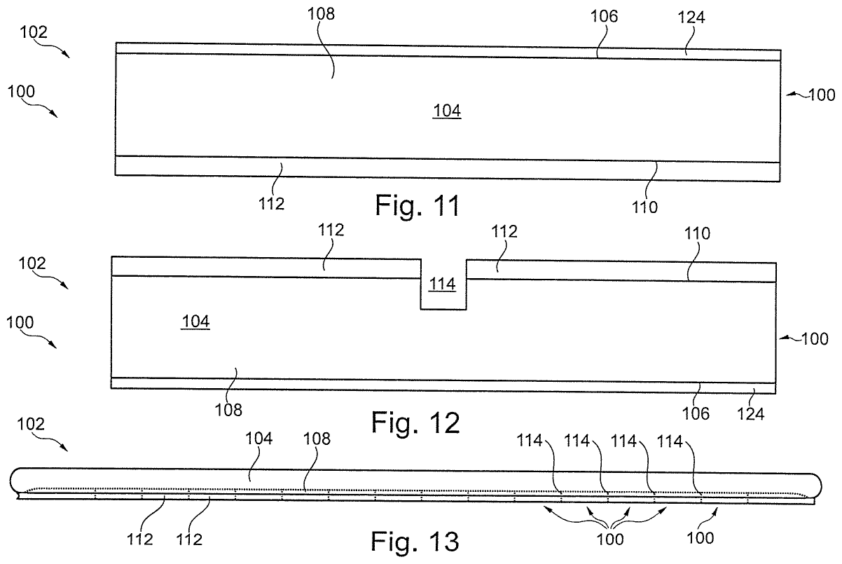

FIG. 11 to FIG. 17 show cross-sectional views of structures obtained during carrying out a method of separating electronic components 100 from a wafer 102 according to another exemplary embodiment.

Referring to FIG. 11, a wafer 100 may be provided with a central semiconductor substrate 104 having at a front side 106 with an active region 108 and a back end of the line structure 124 thereon. On the back side 110 of the semiconductor substrate 104, a functional layer 112 may be attached. Hence, FIG. 11 shows wafer 102 after grinding and lamination of functional layer 112, which may be embodied as back side tape.

Referring to FIG. 12, back side groove 114 may be formed by mechanical dicing through functional layer 112 and into the back side 110 of the semiconductor substrate 104. Said mechanical dicing process may be executed from the back side 110, wherein a back side alignment process may be advantageous.

Referring to FIG. 13, an overview over the whole wafer 102 is given. Optionally, there may be no cutting across the wafer edge for stabilization purposes.

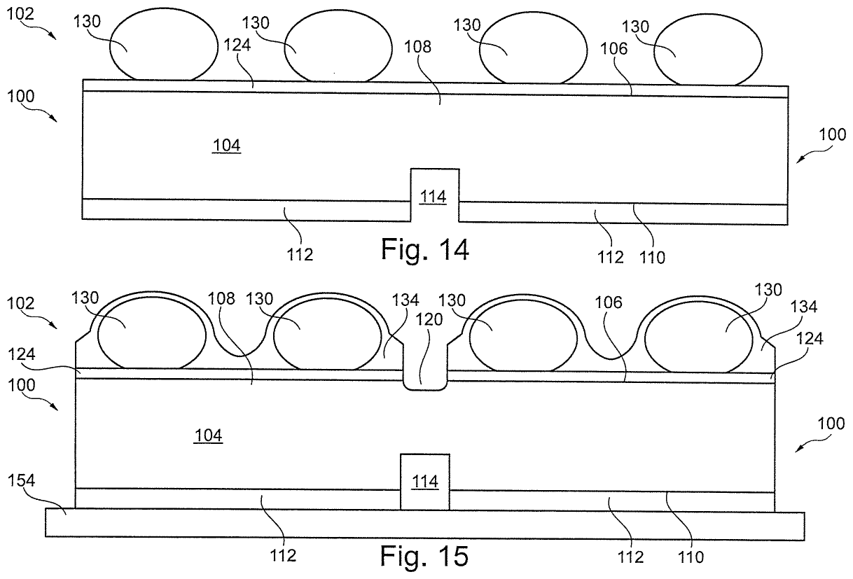

Referring to FIG. 14, electrically conductive connection structures 130, such a solder balls, may be attached to the back end of the line structure 124 for electric connection purposes.

Referring to FIG. 15, a plasma resistant coating 134 may be formed to cover the electrically conductive connection structures 130. The wafer 102 may be mounted at its functional layer 112 on a dicing tape 154. Thereafter, a laser grooving process is carried out for forming an exterior portion 120 of a groove extension 116 (shown completely in FIG. 16).

Referring to FIG. 16, an interior portion 122 of the groove extension 116 is formed by plasma dicing. A through hole 118 is formed extending through the wafer 102 for separating individual electronic components 100 by the combination of the back side groove 114 and the groove extension 116 (composed of its interior portion 122 and its exterior portion 120).

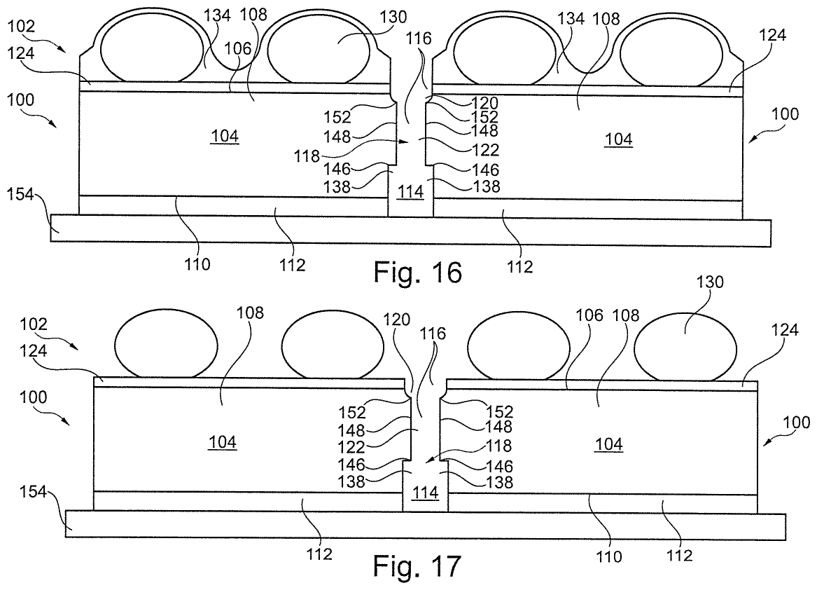

Referring to FIG. 17, the plasma resistant coating 134 is removed by a water rinse process. The individual electronic components 100 may be removed from the dicing tape 154 and may be further processed.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method of separating electronic components from a wafer, wherein the method comprises:
providing the wafer with a semiconductor substrate having a front side with an active region and having a back side covered by a functional layer, said wafer comprising a plurality of integrally connected electronic components arranged side-by-side;
forming a back side groove extending through the functional layer into the semiconductor substrate between adjacent electronic components; and
forming a groove extension connecting to the back side groove to thereby form a through hole extending through the front side for separating adjacent electronic components from each other, wherein said back side groove is formed with a maximum horizontal width larger than a maximum horizontal width of said groove extension.

2. The method according to claim 1, wherein the method comprises forming the back side groove by mechanically dicing or by laser dicing.

3. The method according to claim 1, wherein the method comprises forming the groove extension by processing from the front side until the groove extension connects with the back side groove.

4. The method according to claim 1, wherein the method comprises forming at least part of the groove extension by plasma dicing.

5. The method according to claim 1, wherein the method comprises forming the groove extension by two processing stages.

6. The method according to claim 1, wherein the method comprises forming an exterior portion of the groove extension extending up to the front side by laser grooving.

7. The method according to claim 6, wherein the method comprises forming an interior portion of the groove extension vertically between the back side groove and the exterior portion by plasma dicing.

8. The method according to claim 1, wherein the method comprises providing the semiconductor substrate with a back end of the line structure on the active region and forming the groove extension to extend through the back end of the line structure.

9. The method according to claim 1, comprising at least one of the following features:
wherein the method comprises forming the back side groove with a maximum horizontal width in a range from 20 μm to 50 μm, in particular in a range from 25 μm to 35 μm;
wherein the method comprises forming an exterior portion of the groove extension with a maximum horizontal width in a range from 10 μm to 35 μm, in particular in a range from 15 μm to 25 μm;
wherein the method comprises forming an interior portion of the groove extension with a maximum horizontal width in a range from 5 μm to 30 μm, in particular in a range from 10 μm to 20 μm.

10. The method according to claim 1, wherein the method comprises forming the back side groove wider than an exterior portion of the groove extension, wherein in particular an interior portion of the groove extension is formed narrower than the exterior portion of the groove extension.

11. The method according to claim 10, wherein the method comprises forming the interior portion of the groove extension with substantially vertical sidewalls.

12. The method according to claim 10, wherein the method comprises forming a concave tapering section at an interface between the exterior portion of the groove extension and the interior portion of the groove extension.

13. The method according to claim 10, wherein the method comprises forming a concave tapering section at an interface between the back side groove and the interior portion of the groove extension.

14. The method according to claim 1, wherein the method comprises:
forming electrically conductive connection structures on the front side and embedding the electrically conductive connection structures in a temporary protection carrier;
thereafter thinning the semiconductor substrate at the back side;
thereafter forming said functional layer on the back side of the thinned semiconductor substrate before forming said back side groove; and
removing said temporary protection carrier after forming said back side groove.

15. The method according to claim 1, wherein the method comprises
forming electrically conductive connection structures on the front side and coating the electrically conductive connection structures by a plasma resistant coating;
thereafter forming said groove extension in the semiconductor substrate and extending through the plasma resistant coating; and
thereafter removing said plasma resistant coating.

16. An electronic component, which comprises:
a semiconductor substrate;
an active region at a front side of the semiconductor substrate; and
a functional layer on a back side of the semiconductor substrate;
wherein a sidewall of the electronic component has a notch extending laterally into
the functional layer and into a connected portion of the semiconductor substrate.

17. The electronic component according to claim 16, wherein the sidewall has a step between the notch and a further connected portion of the semiconductor substrate.

18. The electronic component according to claim 17, wherein the further connected portion has a vertical section adjacent to the step.

19. The electronic component according to claim 18, comprising one of the following features:
wherein the further connected portion has a further notch adjacent to the vertical section, wherein more particularly the notch extends laterally deeper into the semiconductor substrate than the further notch;
wherein the vertical section of the further connected portion extends from the step straight up to the front side.

20. The electronic component according to claim 16, comprising at least one of the following features:
wherein a transition between the functional layer and the connected portion of the semiconductor substrate at the notch is continuous and stepless;
wherein the functional layer comprises at least one of a protection layer, an isolation layer, a metallization layer, a plastic layer, a die attach layer, an opaque layer, and an optical contrast enhancing layer;
comprising a back end of the line structure on the active region;
comprising at least one electrically conductive connection structure on or above the active region, in particular on a back end of the line structure on the active region;
wherein the sidewall has the notch extending along an entire circumference of the electronic component.
